(19) United States
(12) Patent Application Publication
(10) Pub. No.: US 2023/0203640 A1
(43) Pub. Date: Jun. 29, 2023

(54) EFFUSION CELL FOR OUTGASSING MEASUREMENTS

(71) Applicant: The Johns Hopkins University, Baltimore, MD (US)

(72) Inventors: John R. Nichols, Columbia, MD (US); Mihaela Ballarotto, Columbia, MD (US); Sungshan C. Chiang, Ellicott City, MD (US); Christian W. Drabenstadt, Savage, MD (US); Kathleen E. Ortel, Glenwood, MD (US); Curt A. Walsh, New Market, MD (US)

(21) Appl. No.: 17/973,887

(22) Filed: Oct. 26, 2022

Related U.S. Application Data
(60) Provisional application No. 63/293,846, filed on Dec. 27, 2021.

(51) Int. Cl. C23C 14/24; C23C 16/455

(52) U.S. Cl. CPC C23C 14/243; C23C 16/455

(57) ABSTRACT

Effusion cells suitable for testing the outgassing of samples, such as flight components, during various temperatures are provided. The effusion cells include an enclosure structure including a loading door (LD) having a LD-open state and a LD-closed state, a trapdoor (TD) having a TD-open state and a TD-closed state, and an outgassing orifice. The enclosure structure defines an internal compartment when the LD is in the LD-closed state and the TD is in the TD-closed state, and wherein the outgassing orifice connects the internal compartment to an external environment, such as an interior portion of a vacuum chamber in which the effusion cell may be placed during operation.

### CROSS-REFERENCE TO RELATED APPLICATIONS

This application is a claims priority to and the benefit of prior-filed, U.S. Provisional Application No. 63/293,846, filed Dec. 27, 2021, the content of which is herein incorporated by reference in its entirety.

### STATEMENT OF GOVERNMENTAL INTEREST

This invention was made with Government support under contract number NNN12AA01C awarded by the National Aeronautics and Space Administration (NASA). The Government has certain rights in the invention.

### TECHNICAL FIELD

Example embodiments relate generally to effusion cells for testing the outgassing of samples, such as flight components, during various temperatures, in which the effusion cells include a loading door (LD) and a trapdoor configured to enable seamless transition from a bake-out operation to a verification (e.g., testing) operation without breaking vacuum between each operation.

### BACKGROUND

Vacuum outgassing tests are generally required for materials independently or flight components including an assembly of multiple individual parts and/or materials if such materials and/or flight components are intended for space flight use. Such materials and/or flight components, for instance, typically must comply with the outgassing test criteria related to the concern for controlling contaminates and verifying that they have been prevented or abated such that the hardware will meet performance requirements. ASTM E 1559 is one commonly utilized test method for evaluating the outgassing of materials and/or flight components for outgassing characteristics.

### BRIEF SUMMARY

One or more non-limiting, example embodiments address one or more of the aforementioned problems. Example embodiments include an effusion cell including an enclosure structure having a loading door (LD) with an LD-open state and an LD-closed state, as well as a trapdoor (TD) having a TD-open state and a TD-closed state. The effusion cell also includes an outgassing orifice. The enclosure structure of the effusion cell defines an internal compartment when the LD is in the LD-closed state and the TD is in the TD-closed state, and the outgassing orifice connects the internal compartment to an external environment, such as the inside of a vacuum chamber, when the effusion cell is housed within a vacuum chamber during operation.

In another example embodiment, a system includes an effusion cell, such as those described and disclosed herein, and a quartz crystal microbalance, such as a cryogenic quartz crystal microbalance (CQCM), located outside of the outgassing orifice along a first imaginary line extending perpendicularly through the outgassing orifice at least when the LD is in the LD-closed state and the TD is in the TD-closed state. The system may also include a residual gas analyzer (RGA) located outside of the TD along a second imaginary line extending perpendicularly through a trap opening defined the TD in the TD-open state.

In yet another example embodiment, a method of measuring an amount of outgassing from a sample includes the following: (i) providing an effusion cell, such as those described and disclosed herein, (ii) positioning the sample inside of the effusion cell, in which the LD is positioned in the LD-closed state and the TD is positioned in the TD-open state, and positioning the effusion cell within a vacuum chamber; (iii) generating a vacuum inside the vacuum chamber and the effusion cell via a vacuum source operatively connected to the vacuum chamber; (iv) initiating a bake-out operation by increasing the temperature of the internal compartment to a desired bake-out temperature; (v) monitoring a rate and/or amount of outgassing from the sample via a residual gas analyzer (RGA) located outside of a trap opening defined by the TD in the TD-open state, and along a second imaginary line extending perpendicularly through the trap opening; (vi) initiating a verification operation by adjusting the TD to the TD-closed state once the rate of outgassing from the sample detected by the RGA reaches below a predetermined level for a predetermined time duration, wherein the internal compartment is in operative communication with the vacuum chamber via only the outgassing orifice, and adjusting the temperature of the internal compartment to a predefined testing temperature; and (vi) monitoring a rate and/or amount of outgassing from the sample via a CQCM located outside of the outgassing orifice along a first imaginary line extending perpendicularly through the outgassing orifice when the LD is in the LD-closed state and the TD is in the TD-closed state.

### BRIEF DESCRIPTION OF THE DRAWINGS

Example embodiments now will be described more fully hereinafter with reference to the accompanying drawings, in which some, but not all embodiments are shown. Indeed, this invention may be embodied in many different forms and should not be construed as limited to the embodiments set forth herein; rather, these embodiments are provided so that this disclosure will satisfy applicable legal requirements. Like numbers refer to like elements throughout, and wherein:

FIG. 1 illustrates an isometric view of an effusion cell in accordance with certain embodiments;

FIG. 2A is a schematic of a top-view of an effusion cell located within a vacuum chamber in accordance with certain embodiments;

FIG. 2B is a schematic of a side-view of the effusion cell of located within a vacuum chamber of FIG. 2A in accordance with certain embodiments;

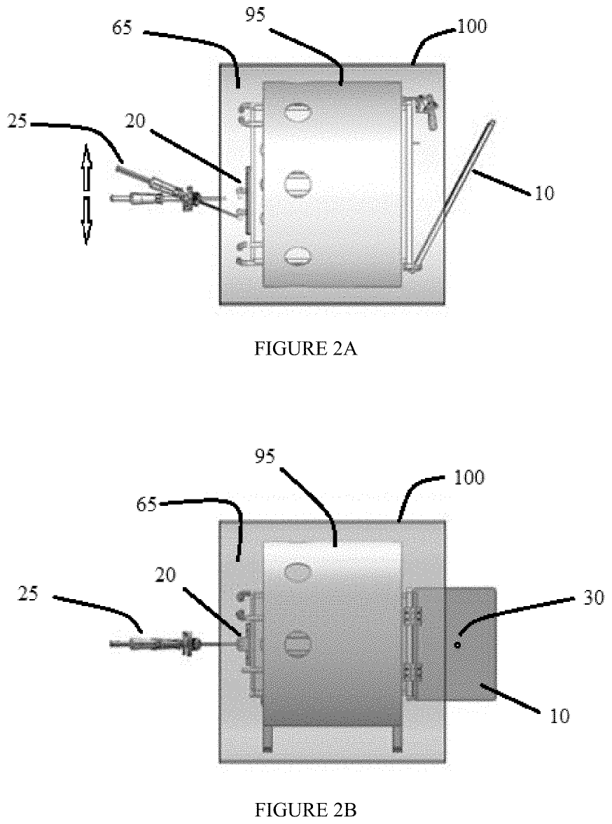

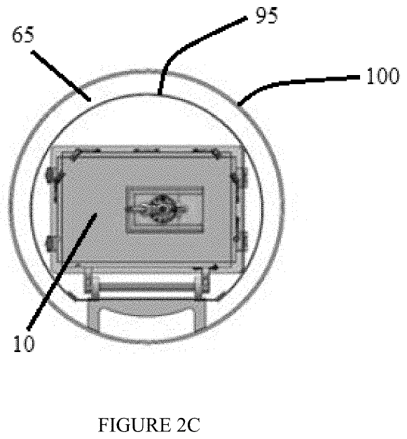

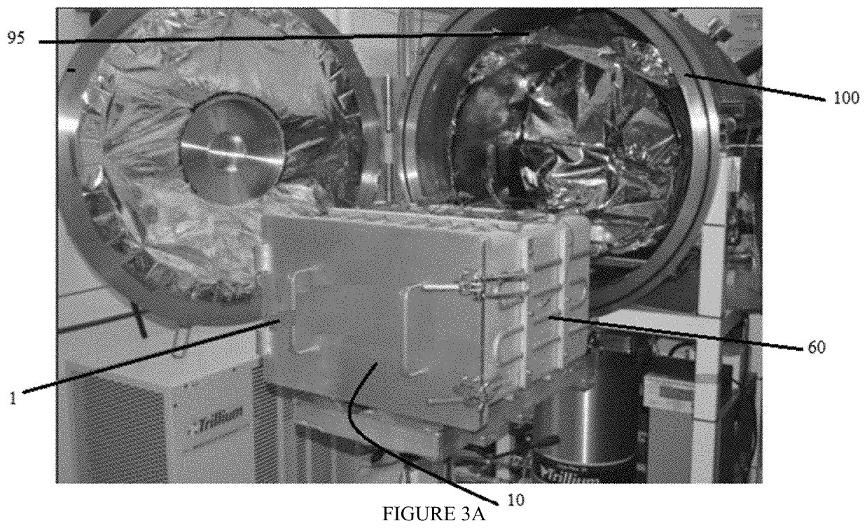

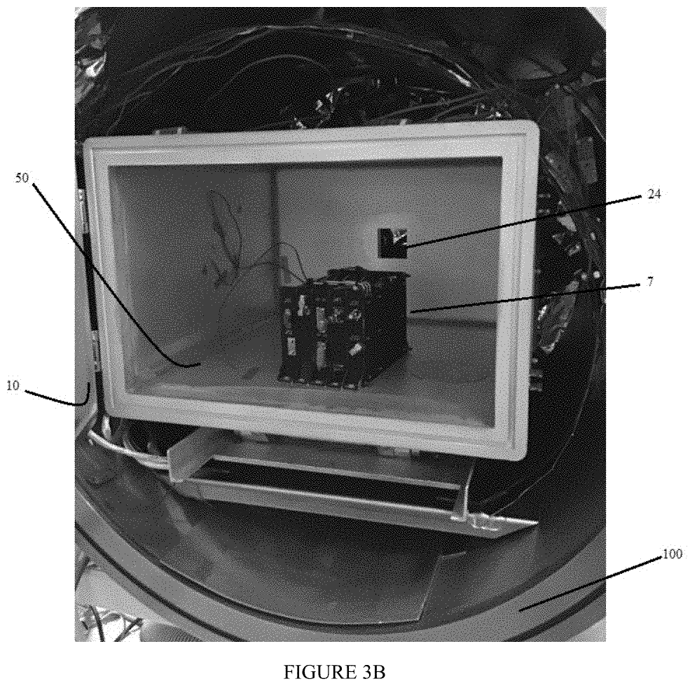

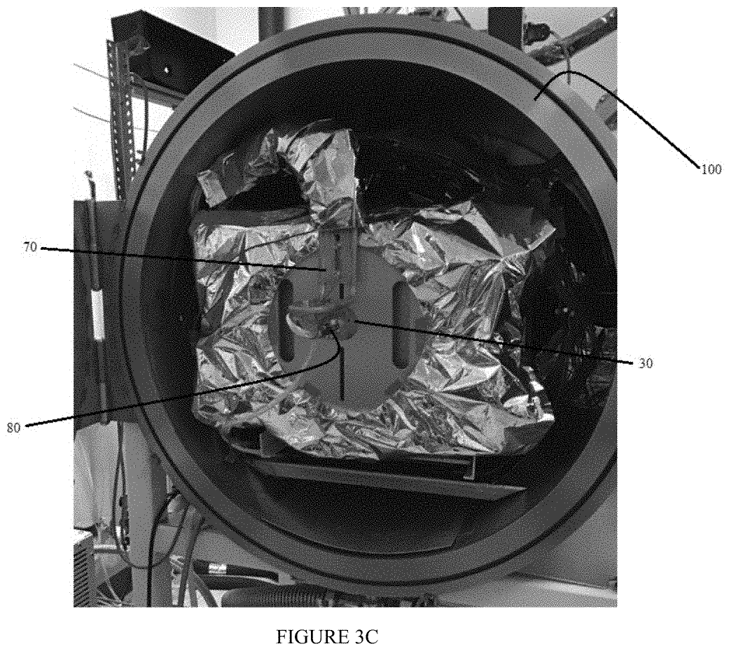

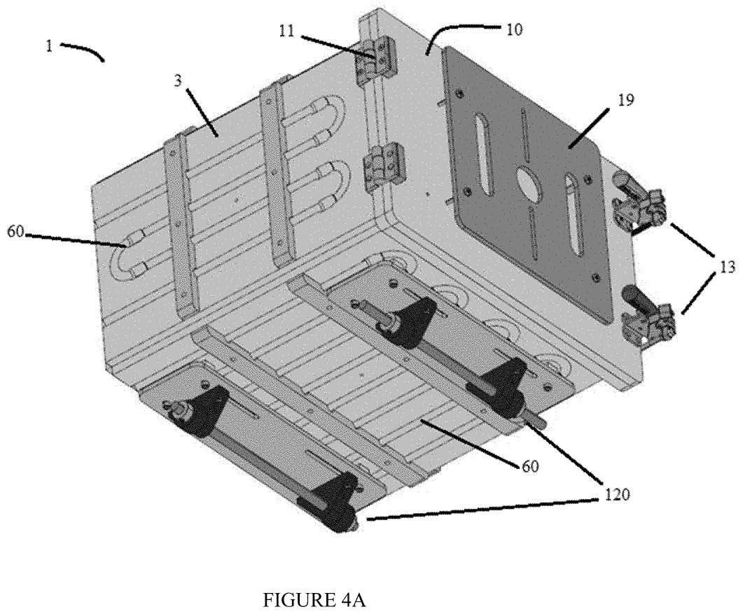

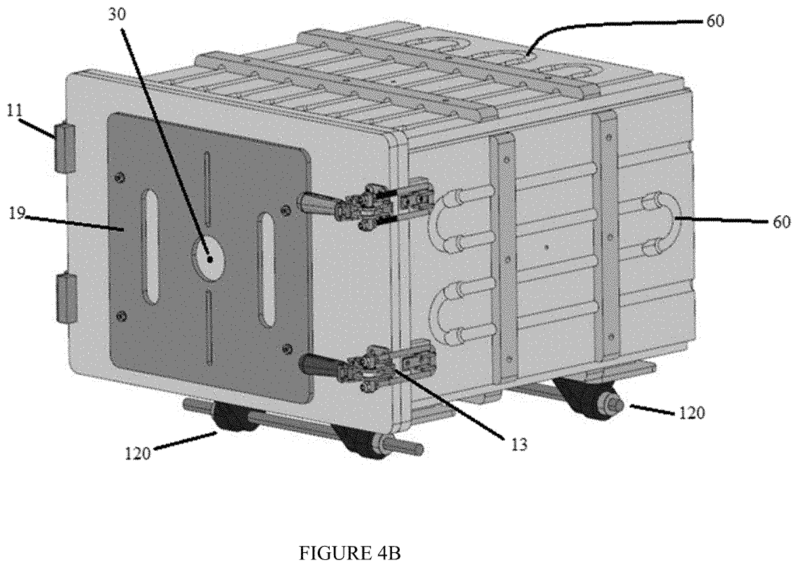

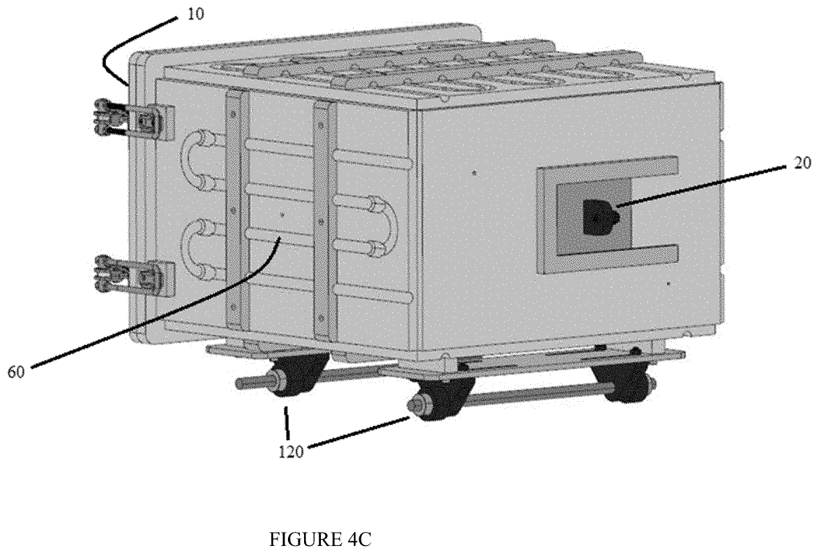

FIG. 0 is a schematic of a loading-view of the effusion cell of located within a vacuum chamber of FIG. 2A in accordance with certain embodiments;

FIG. 3A illustrates an effusion cell prior to be loaded into a vacuum chamber in accordance with certain embodiments;

FIG. 3B illustrates a sample located in an open effusion cell, in which the loading door (LD) and the trapdoor (TD) are both open in accordance with certain embodiments;

FIG. 3C illustrates the effusion cell of FIG. 3B with the LD closed and a cryogenic quartz crystal microbalance (CQCM) mounted outside of the effusion cell and aligned with an outgassing orifice in accordance with certain embodiments; and

FIGS. 4A-4C are different views of an effusion cell having rollers attached thereto for ease of loading and unloading of the effusion cell in relation to a vacuum chamber in accordance with certain embodiments.

### DETAILED DESCRIPTION

Non-limiting, example embodiments will be described more fully hereinafter with reference to the accompanying drawings, in which some, but not all embodiments are shown. Indeed, this invention may be embodied in many different forms and should not be construed as limited to the embodiments set forth herein; rather, these embodiments are provided so that this disclosure will satisfy applicable legal requirements. As used in the specification, and in the appended claims, the singular forms “a”, “an”, “the”, include plural referents unless the context clearly dictates otherwise.

Example embodiments relate generally to a box-level effusion cell that enables high-precision outgassing rate measurements of small hardware assemblies, such as electronics boxes and mechanical structures, for example, up to 17 inches by 18 inches by 10 inches (17″×18″×10″) in size in accordance with certain embodiments. The effusion cell may be made from a variety of metals or metal alloys from which the wall(s) and/or door(s) are formed. For example only, the effusion cell may, in accordance with certain embodiments, be formed from a half-inch thick aluminum box constructed with full-penetration welding on all sides. The effusion cell may include a heating/cooling element, such as a continuous tubing (e.g., brazed copper tubing) located on exterior surface for heating/cooling of the internal compartment of the effusion cell where the sample (e.g., hardware assembly) will be located for outgassing measurement. In accordance with certain embodiments, the effusion sell has a box structure including six (6) sides when closed. For example, a front face of the effusion cell may include a loading door (LD), such as a hinged door that may swing all the way open to allow for loading large hardware, and latches that enable the LD to be closed with, for example, a tight metal-on-metal seal. The effusion cell may also include a trap door (TD), for example, located on the back side of the effusion cell. The TD, for example, can be open for molecular flow bake-out operation and then closed for outgassing measurements (e.g., a verification operation) without the need to break a vacuum pulled on the system generated during the bake-out operation and utilized during a verification operation that measures the outgassing of the sample during a desired operating temperature. An outgassing orifice, which may resemble a pinhole, may be located anywhere on the effusion cell. For example, the outgassing orifice may be located on the LD, and a mounting bracket for a quartz crystal microbalance, such as a cryogenic quartz crystal microbalance (CQCM). A CQCM, for example, may be mounted outside of the effusion cell but within the vacuum chamber, and aligned with the outgassing orifice. The mass of the outgas from the sample may be collected by the CQCM and analyzed for a determination of the rate and/or total mass of outgas released from the sample, such as via calculations detailed in the ASTM E1559 standard or a procedure modified from the calculations detailed in the ASTM E1559 standard, for example, to account for the size of the outgassing orifice and the distance between the CQCM and the outgassing orifice.

In accordance with certain embodiments, for example, the effusion cell may include a box-level effusion cell allows for outgassing measurements of flight assemblies that are bigger than a standard cylindrical effusion cell. Previously, the outgassing rates for these assemblies had to be determined from measurements conducted with material samples or individual parts, which does not always accurately represent the exposed surface area of the final configuration. Accordingly, the measured outgassing values are not necessarily accurate for the assembled combination of parts (e.g., flight assembly).

The effusion cell, in accordance with certain embodiments, provides for efficient thermal transitions (e.g., of the internal compartment that houses the sample), and can support dynamic thermal testing up to, for example, 200 degrees Celsius (° C.) to as low as −130° C. In accordance with certain embodiments, the effusion cell may include enough mass (e.g., material selection and wall thickness) to maintain an even temperature on all six sides (e.g., for a box configuration), and the length and path of the cooling/heating loop allows for extreme differences (>200° C.) between a chamber shroud and the effusion cell with minimal blanketing. In this regard, precise thermal control contributes to the accuracy of outgassing measurements, and the effusion cell's cooling/heating loop design and wall thickness allow for control within, for example, ±3° C. for large masses (up to 30 kg) and down to, for example, ±1.5° C. for smaller masses.

As noted above, the effusion cell may also include a TD that can be left open during pump-down (e.g., generation of a vacuum when the effusion cell is located inside of a vacuum chamber) and a bake-out operation, and then closed from outside of the vacuum chamber, without breaking vacuum within the vacuum chamber and the effusion cell. This feature allows for a molecular flow bake-out operation immediately prior to testing for outgassing of a sample, as outgassed material during the bake-out operation can easily leave the effusion cell. This ability not only shortens the time needed with the hardware to complete a vacuum bake-out operation and certification steps, but also ensures that outgassing measurements at cryogenic temperatures are taken with fully dry hardware. In accordance with certain embodiments, the TD, for example, may slide closed with a tight seal, ensuring that the outgassing orifice is the only exit route for the outgassed material during the measurement phase (e.g., the verification operation).

Certain embodiments include an effusion cell including an enclosure structure including an LD having a LD-open state and a LD-closed state and a TD having a TD-open state and a TD-closed state. The effusion cell may also include an outgassing orifice. The enclosure structure of the effusion cell may define an internal compartment when the LD is in the LD-closed state and the TD is in the TD-closed state, and wherein the outgassing orifice connects the internal compartment to an external environment, such as the inside of a vacuum chamber when the effusion cell is housed within a vacuum chamber during operation.

Although the effusion cell may be embodied in a variety of shapes, the effusion cell in accordance with certain embodiments may have a box-structure including at least one stationary wall, such as six walls when the LD and TD are each in a closed state. For example, the effusion cell may include 4 or 5 fixed or stationary wall in which the LD defines a moveable wall due to the opening/closing feature of the LD. By way of the of example, the effusion cell may include a box-structure including five stationary walls, in which one of the stationary walls includes a first stationary wall having the TD either formed therein or attached thereto.

In accordance with certain embodiments, the effusion cell may include a TD-actuator configured to adjust the TD from the TD-open state to the TD-closed state, adjust the TD from the TD-closed state to the TD-open state, or both. The TD-actuator, for example, may include a manually-operated mechanical connection. For instance, the manually-operated mechanical connection may include a lever attached to the TD and extends through a shroud and/or vacuum chamber wall when the effusion cell is housed within a vacuum chamber for operation. In this regard, a user may manually close and/or open the TD when desired. Additionally or alternatively, the TD-actuator may include an electrically motorized mechanical drive or an air-powered mechanical drive that may be operated by a user located outside of the vacuum chamber. In accordance with certain embodiments, the TD-actuator may include a pneumatic control (e.g., air-powered mechanical drive) with the use of metal tubing for the pneumatic control since the tubing for the pneumatic control will be located within the vacuum generated during operation. In accordance with certain embodiments, the TD-actuator may include an electric control (e.g., an electrically motorized mechanical drive) in which a switch outside of the vacuum chamber may be engaged by a user to close (e.g., move the TD to the TD-closed state) and/or open the TD (e.g., move the TD to the TD-open state). Beneficially, the incorporation of the TD-actuator enables transitioning the effusion cell from a bake-out operation to a testing or verification operation without the need to break vacuum to reconfigure the effusion cell, which would undesirably all moisture and possibly other contaminates back into the effusion cell prior to the testing or verification operation.

In accordance with certain embodiments, the effusion cell may include a temperature-control element configured to increase, decrease, or hold constant an internal temperature of the internal compartment. The temperature-control element, in accordance with certain embodiments, may include a tubing system configured to be connected to a heating source and/or a cooling source separate from the effusion cell. For instance the tubing system may operatively connected to a heating source and a cooling source located outside of the vacuum chamber when the effusion cell is housed therein for operation. In this regard, the tubing system provides the flexibility of utilizing the same system for providing heat and removing heat (e.g., cooling effect) as well as the increased flexibility of enabling the use of variety of different heat sources (e.g., different heated fluids such as oil, steam, etc.) and different chilling or cooling sources (e.g., chilled water, liquid nitrogen, etc.). The connection of the tubing system to the variety of heating and/or cooling sources may beneficial be selected and/or performed outside of the vacuum chamber when the effusion cell is housed therein for operation.

By way of example, the tubing system may be located on an exterior surface of the effusion cell, on an inside surface of the effusion cell, or embedded within at least one stationary wall of the effusion cell (e.g., the tubing system may pass or be formed by an interior portion of the wall(s)). Locating the tubing system on an exterior surface of the effusion cell may be easiest from an installation and maintenance perspective. For example, the tubing system may be located along the exterior surface of one or more walls of the effusion cell. For example, the effusion cell may include five stationary walls, wherein a first stationary wall includes TD either formed therein or attached thereto, and the tubing system may have a serpentine path that is in contact with at least four of the five stationary walls.

In accordance with certain embodiments, the tubing system includes a total path length in contact with the exterior surface of the effusion cell when the LD is in the LD-closed state and the TD is in the TD-closed state, and the exterior surface defines an external volume, in cubic feet (ft³), of the effusion cell. In this regard, the effusion cell may have a first ratio between the total path length, in feet (ft), and the external volume, in ft³, from about 20:1 to about 50:1, such as at least about any of the following: 20:1, 22:1, 25:1, 28:1, 30:1, 32:1, and 35:1, and/or at most about any of the following: 50:1, 45:1, 40:1, and 35:1. Additionally or alternatively, the tubing system includes a total path length in contact with the exterior surface of the effusion cell when the LD is in the LD-closed state and the TD is in the TD-closed state, and the exterior surface defines an external surface area, in square feet (ft²), of the effusion cell. In this regard, the effusion cell may have a second ratio between the total path length (in ft) and the external surface area (in ft²) from about 2:1 to about 10:1, such as at least about any of the following: 2:1, 3:1, 4:1, and 5:1, and/or at most about any of the following: 10:1, 9:1, 8:1, 7:1, 6:1, and 5:1.

In accordance with certain embodiments, the tubing system may be formed from a metal or metal alloy, such as aluminum or an aluminum alloy. In accordance with certain embodiments, the effusion cell may be formed from one or more grades of stainless steel, copper, or aluminum.

In accordance with certain embodiments, the outgassing orifice defines an open area including from about 3 to about 20 square millimeters (mm²), such as at least about any of the following: 3, 4, 5, 6, 7, 8, 9, and 10 mm², and/or at most about any of the following: 20, 18, 16, 14, 12, and 10 mm². Additionally or alternatively, the outgassing orifice defines an open area and the internal compartment has an internal volume (when the LD and TD are each in their closed state). In this regard, the effusion cell may have a third ratio between the open area (mm²), and the internal volume (m³) from about 60:1 to about 400:1, such as at least about any of the following: 60:1, 80:1, 100:1, 120:1, 140:1, 160:1, 180:1, and 200:1, and/or at least about any of the following: 400:1, 380:1, 360:1, 340:1, 320:1, 300:1, 280:1, 260:1, 240:1, 220:1, and 200:1. The outgassing orifice, for example, may be located at any location of the effusions cell. In accordance with certain embodiments, however, the outgassing orifice may be formed or located in LD.

The effusion cell, in accordance with certain embodiments, may also include a mounting bracket attached to or formed as part of or an external surface of the effusion cell. The mounting bracket, for example, may be located and configured to mount a quartz crystal microbalance assembly, such as a cryogenic quartz crystal microbalance (CQCM), outside of the outgassing orifice along an imaginary line extending perpendicularly through the outgassing orifice at least when the LD is in the LD-closed state and the TD is in the TD-closed state. In accordance with certain embodiments, a gap between a mounted CQCM and the outgassing orifice includes from about 0.5 to about 3 cm, such as at least about any of the following: 0.5, 0.8, 1, 1.2, and 1.5 cm, and/or at most about any of the following: 3, 2.8, 2.5, 2.2, 2, 1.8, and 1.5 cm.

In accordance with certain embodiments, the LD includes a hinged door that defines a loading opening when in the LD-open state. As noted above, the outgassing orifice may be located within the LD. In such embodiments, the mounting bracket may be attached to the LD. The LD, for example, may include one or more clamps to facilitate a tight seal between the LD and the stationary walls of the effusion cell. Additionally or alternatively, the TD may be located on an opposite face of the effusion cell from the LD. Additionally or alternatively, the TD may define a TD-opening that, for example, may be smaller than the side wall upon which the TD is incorporated. The TD, by way of example only, may include a guillotine structure in which the TD-open state corresponds to a raised location of the TD and the TD-closed state corresponds to a lowered location of the TD. In this regard, the TD may slide alone an imaginary plane that is parallel to (and preferably adjacent) the stationary wall in which the TD is incorporated.

In accordance with certain embodiments, the effusion cell may include a pressure gauge and/or monitor located within the internal compartment of the effusion cell. The pressure gauge and/or monitor may measure the pressure present within the effusion cell (e.g., pressure of the internal compartment) during the testing or verification operation. After the bake-out operation and initiation of the verification operation to measure outgassing of the sample (e.g., outgassing associated with gas being released from the bulk of the sample), the pressure within the effusion cell can be monitored as a function of time during the verification operation. For example, increases in the pressure within the effusion cell may be associated with outgassing from the sample during the verification operation. The pressure increase, for example, may be utilized to measure and/or evaluate the rate and total mass of outgassing during the verification operation. In this regard, the effusion cell may or may not utilize the CQCM and/or outgassing orifice. In accordance with certain embodiments, the rate and/or total mass of outgassing during the verification operation may be evaluated by both the use of the CQCM and the pressure gauge to provide increased confidence in the measurement value of outgassing during the verification operation.

In accordance with certain embodiments, the effusion cell the at least one stationary, the TD, and the LD may be formed from a metal or metal alloy, such as aluminum or an aluminum alloy. In accordance with certain embodiments, the effusion cell may be formed from one or more grades of stainless steel, copper, or aluminum.

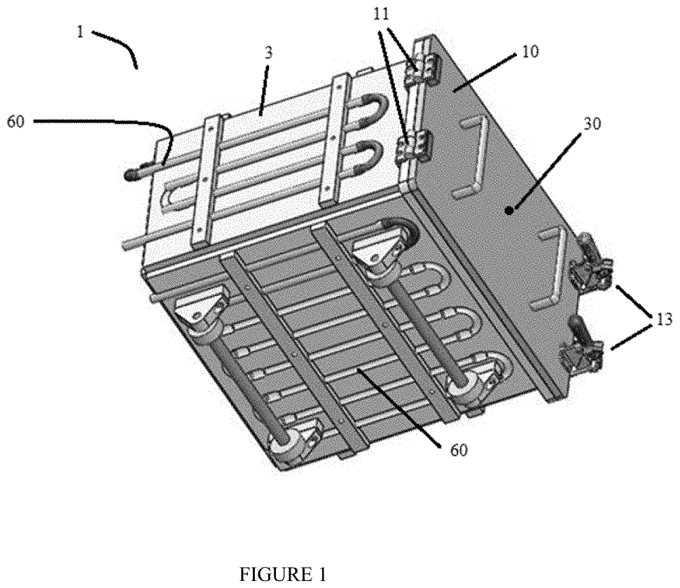

FIG. 1 illustrates an isometric view of an effusion cell 1 in accordance with certain embodiments. The effusion cell 1 includes a plurality of stationary walls 3 and a LD 10, which includes hinges 11 and clamps 13. In this particular embodiment, the LD 10 includes the outgassing orifice 30. As also shown in FIG. 1, the effusion cell 1 includes a tubing system 60 adjacent the stationary walls 3. Although not shown in FIG. 1, the TD is located on the opposing face to the LD.

FIG. 2A illustrates a schematic of a top-view of an effusion cell located within a vacuum chamber in accordance with certain embodiments. FIG. 2B illustrates a schematic of a side-view of the effusion cell of located within a vacuum chamber of FIG. 2A in accordance with certain embodiments. FIG. 2C illustrates a schematic of a loading-view of the effusion cell of located within a vacuum chamber of FIG. 2A in accordance with certain embodiments. As illustrated by FIGS. 2A-2C, the effusion cell 1 may be located within a shroud 95 and a vacuum chamber 100 that defines an external environment 65 with respect to a closed effusion cell. As shown in FIGS. 2A-2B, the TD 20 is located on an opposing face of the effusion cell 1 with respect to the LD 10. Also illustrated is the incorporation of a TD-actuator 25 including a manually-operated mechanical connection that is attached to the TD 20 at a first end and extends through the vacuum chamber 100 and terminates at a second end located outside of the vacuum chamber. As illustrated by the arrows on FIG. 2A, the manually-operated mechanical connection (e.g., a movable lever) may be moveable along in the directions of the arrows to switch the TD 20 from the TD-open state to the TD-closed state.

FIG. 3A shows an effusion cell prior to be loaded into a vacuum chamber in accordance with certain embodiments. FIG. 3B shows a sample 7 located in an open effusion cell showing the internal compartment 50 of the effusion cell, in which the LD and the TD are both open in accordance with certain embodiments. Also illustrated by FIG. 3B, the TD is in the TD-open state to show the trap opening 24. FIG. 3C shows the effusion cell of FIG. 3B with the LD closed and a mounting bracket 70 attached to the LD. A CQCM 80 is mounted outside of the effusion cell and aligned with an outgassing orifice 30 in accordance with certain embodiments.

FIGS. 4A-4C illustrate renderings of different view of an effusion cell 1 having rollers 120 attached thereto for ease of loading and unloading of the effusion cell in relation to a vacuum chamber in accordance with certain embodiments. FIG. 4C illustrates a TD 20 having a guillotine-type configuration.

In another aspect, example embodiments include a system including an effusion cell, such as those described and disclosed herein, and a quartz crystal microbalance, such as a CQCM, located outside of the outgassing orifice along a first imaginary line extending perpendicularly through the outgassing orifice at least when the LD is in the LD-closed state and the TD is in the TD-closed state. The system may also include an RGA located outside of the TD along a second imaginary line extending perpendicularly through a trap opening defined the TD in the TD-open state.

In accordance with certain embodiments, the system may further include a heat source operatively connected to a first temperature-control element (e.g., the tubing system) configured to increase and/or hold constant an internal temperature of the internal compartment. Additionally or alternatively, the system may further include a cooling source operatively connected to a second temperature-control element (e.g., the tubing system) configured to decrease, or hold constant an internal temperature of the internal compartment.

In accordance with certain embodiments, the system may further include a vacuum source (e.g., a vacuum pump, etc.) and a vacuum chamber configured to house the effusion cell, wherein the vacuum source is operatively connected to the vacuum chamber. The vacuum chamber, for example, may include at least a first vacuum chamber-orifice. A manually-operated mechanical connection operatively connected to the TD and extending through the first vacuum chamber-orifice for engagement by a user. Additionally or alternatively, an electrically motorized mechanical drive or an air-powered mechanical drive operatively connected to the TD where power lines and/or air lines extend through the first vacuum chamber-orifice.

In yet another aspect, example embodiments include a method of measuring the amount of outgassing from a sample. The method may include the following: (i) providing an effusion cell, such as those described and disclosed herein, (ii) positioning the sample inside of the effusion cell, in which the LD is positioned in the LD-closed state and the TD is positioned in the TD-open state, and positioning the effusion cell within a vacuum chamber; (iii) generating a vacuum inside the vacuum chamber and the effusion cell via a vacuum source operatively connected to the vacuum chamber; (iv) initiating a bake-out operation by increasing the temperature of the internal compartment to a desired bake-out temperature; (v) monitoring a rate and/or amount of outgassing from the sample via a residual gas analyzer (RGA) located outside of a trap opening defined by the TD in the TD-open state, and along a second imaginary line extending perpendicularly through the trap opening; (vi) initiation a verification operation by adjusting the TD to the TD-closed state once the rate of outgassing from the sample detected by the RGA reaches below a predetermined level for a predetermined time duration, wherein the internal compartment is in operative communication with the vacuum chamber via only the outgassing orifice, and adjusting the temperature of the internal compartment to a predefined testing temperature; and (vii) monitoring a rate and/or amount of outgassing from the sample via a CQCM located outside of the outgassing orifice along a first imaginary line extending perpendicularly through the outgassing orifice when the LD is in the LD-closed state and the TD is in the TD-closed state. In accordance with certain embodiments the vacuum inside the vacuum chamber and the effusion cell during the bake-out operation and/or the verification operation includes from about 1×10⁻⁴ to about 1×10⁻⁹ torr.

In accordance with certain embodiments, the desired bake-out temperature includes from about 20 to about 200° C., such as at least about any of the following: 20, 40, 60, 80, and 100° C., and/or at most about any of the following: 200, 180, 160, 140, 120, and 100° C. Additionally or alternatively, monitoring the rate and/or amount (e.g., mass) of outgassing from the sample via the RGA located outside of the trap opening occurs from 12 hours to about 192 hours, such as at least about any of the following: 12, 25, 36, 48, 60, 72, 84, 96, and 108 hours, and/or at most about any of the following: 120, 132, 144, 156, 168, 180, and 192 hours.

In accordance with certain embodiments, initiation of the verification operation occurs after the rate of outgassing from the sample detected by the RGA reaches below the predetermined level for the predetermined time duration, wherein the predetermined level includes a maximum acceptable outgassing rate (g/cm²/s) and the predetermined time duration includes from about 6 hours to about 48 hours, such as at least about any of the following: 6, 12, 18, and 24 hours, and/or at most about any of the following: 48, 36, and 24 hours. Additionally or alternatively, the rate of outgassing below the predetermined level for the predetermined time duration has an average rate (g/cm²/s) with deviations from the average rate over the predetermined time duration not exceeding greater than 10% from the average rate, such as at most any of the following: 10, 8, 6, 4, 2, and 1% from the average rate. In this regard, the outgassing rate may be effectively constant at value below the predetermined level.

In addition, it should be understood that aspects of the various embodiments may be interchanged in whole or in part. Furthermore, those of ordinary skill in the art will appreciate that the foregoing description is by way of example only, and it is not intended to limit the invention as further described in such appended claims. Therefore, the spirit and scope of the appended claims should not be limited to the exemplary description of the versions contained herein.

What is claimed is:

1. An effusion cell, comprising an enclosure structure including:
a loading door (LD) having an LD-open state and an LD-closed state;
a trapdoor (TD) having a TD-open state and a TD-closed state; and
an outgassing orifice, wherein
the enclosure structure defines an internal compartment when the LD is in the LD-closed state and the TD is in the TD-closed state, and
the outgassing orifice connects the internal compartment to an external environment.

2. The effusion cell of claim 1, wherein the effusion cell has a box-structure including at least one stationary wall.

3. The effusion cell of claim 1, wherein the effusion cell has a box-structure including five stationary walls, wherein a first stationary wall of the five stationary walls includes the TD either formed therein or attached thereto.

4. The effusion cell of claim 1, further comprising a TD-actuator configured to adjust the TD from the TD-open state to the TD-closed state, adjust the TD from the TD-closed state to the TD-open state, or both.

5. The effusion cell of claim 4, wherein the TD-actuator comprises a manually-operated mechanical connection, an electrically motorized mechanical drive, or an air-powered mechanical drive.

6. The effusion cell of claim 1, further comprising a temperature-control element configured to increase, decrease, or hold constant an internal temperature of the internal compartment.

7. The effusion cell of claim 6, wherein the temperature-control element comprises a tubing system configured to be connected to a heating source and/or a cooling source separate from the effusion cell.

8. The effusion cell of claim 7, wherein the tubing system is located on an exterior surface of the effusion cell, on an inside surface of the effusion cell, or embedded within at least one stationary wall of the effusion cell.

9. The effusion cell of claim 8, wherein
the tubing system comprises a total path length in contact with the exterior surface of the effusion cell when the LD is in the LD-closed state and the TD is in the TD-closed state,
the exterior surface defines an external volume of the effusion cell, and
a first ratio between the total path length and the external volume is from about 20:1 to about 50:1, such as at least about any of the following: 20:1, 22:1, 25:1, 28:1, 30:1, 32:1, and 35:1, and/or at most about any of the following: 50:1, 45:1, 40:1, and 35:1.

10. The effusion cell of claim 8, wherein
the tubing system comprises a total path length in contact with the exterior surface of the effusion cell when the LD is in the LD-closed state and the TD is in the TD-closed state,
the exterior surface defines an external surface area of the effusion cell, and
a second ratio between the total path length and the external surface area is from about 2:1 to about 10:1, such as at least about any of the following: 2:1, 3:1, 4:1, and 5:1, and/or at most about any of the following: 10:1, 9:1, 8:1, 7:1, 6:1, and 5:1.

11. The effusion cell of claim 1, wherein the outgassing orifice defines an open area from about 3 mm² to about 20 mm², such as at least about any of the following: 3, 4, 5, 6, 7, 8, 9, and 10 mm², and/or at most about any of the following: 20, 18, 16, 14, 12, and 10 mm².

12. The effusion cell of claim 10, wherein
the outgassing orifice defines an open area and the internal compartment has an internal volume, and
a third ratio between the open area and the internal volume is from about 60:1 to about 400:1, such as at least about any of the following: 60:1, 80:1, 100:1, 120:1, 140:1, 160:1, 180:1, and 200:1, and/or at least about any of the following: 400:1, 380:1, 360:1, 340:1, 320:1, 300:1, 280:1, 260:1, 240:1, 220:1, and 200:1.

13. The effusion cell of claim 1, further comprising a mounting bracket attached to or formed as part of or an external surface of the effusion cell, wherein
the mounting bracket is located and configured to mount a quartz crystal microbalance assembly, such as a cryogenic quartz crystal microbalance (CQCM), outside of the outgassing orifice along an imaginary line extending perpendicularly through the outgassing orifice at least when the LD is in the LD-closed state and the TD is in the TD-closed state, and
a gap between a mounted CQCM and the outgassing orifice is from about 0.5 cm to about 3 cm, such as at least about any of the following: 0.5, 0.8, 1, 1.2, and 1.5 cm, and/or at most about any of the following: 3, 2.8, 2.5, 2.2, 2, 1.8, and 1.5 cm.

14. A system, comprising:
an effusion cell comprising an enclosure structure including:
a loading door (LD) having an LD-open state and an LD-closed state;
a trapdoor (TD) having a TD-open state and a TD-closed state; and
an outgassing orifice, wherein
the enclosure structure defines an internal compartment when the LD is in the LD-closed state and the TD is in the TD-closed state, and
the outgassing orifice connects the internal compartment to an external environment;
a cryogenic quartz crystal microbalance (CQCM) located outside of the outgassing orifice along a first imaginary line extending perpendicularly through the outgassing orifice at least when the LD is in the LD-closed state and the TD is in the TD-closed state; and
a residual gas analyzer (RGA) located outside of the TD along a second imaginary line extending perpendicularly through a trap opening defined the TD in the TD-open state.

15. The system of claim 14, further comprising:
a heat source operatively connected to a first temperature-control element configured to increase, or hold constant an internal temperature of the internal compartment; and
a cooling source operatively connected to a second temperature-control element configured to decrease, or hold constant an internal temperature of the internal compartment.

16. The system of claim 14, further comprising a vacuum source operatively connected to a vacuum chamber, wherein the vacuum chamber is configured to house the effusion cell.

17. The system of claim 14, wherein
the vacuum chamber includes at least a first vacuum chamber-orifice,
the effusion cell includes a TD-actuator configured to adjust the TD from the TD-open state to the TD-closed state, to adjust the TD from the TD-closed state to the TD-open state or both, and
the TD-actuator comprises a manually-operated mechanical connection operatively connected to the TD and extending through the first vacuum chamber-orifice for engagement by a user, and an electrically motorized mechanical drive or an air-powered mechanical drive operatively connected to the TD where power lines and/or air lines extend through the first vacuum chamber-orifice.

18. A method of measuring an amount of outgassing from a sample, the method comprising:
(i) providing an effusion cell comprising an enclosure structure including:
a loading door (LD) having an LD-open state and an LD-closed state;
a trapdoor (TD) having a TD-open state and a TD-closed state; and
an outgassing orifice, wherein
the enclosure structure defines an internal compartment when the LD is in the LD-closed state and the TD is in the TD-closed state, and
the outgassing orifice connects the internal compartment to an external environment;
(ii) positioning the sample inside of the effusion cell, wherein the LD is positioned in the LD-closed state and the TD is positioned in the TD-open state, and positioning the effusion cell within a vacuum chamber and sealed;
(iii) generating a vacuum inside the vacuum chamber and the effusion cell via a vacuum source operatively connected to the vacuum chamber;
(iv) initiating a bake-out operation by increasing a temperature of the internal compartment to a desired bake-out temperature;
(v) monitoring a rate and/or amount of outgassing from the sample via a residual gas analyzer (RGA) located outside of a trap opening defined by the TD in the TD-open state, and along a first imaginary line extending perpendicularly through the trap opening;
(vi) initiation a verification operation by adjusting the TD to the TD-closed state once the rate of outgassing from the sample detected by the RGA reaches below a predetermined level for a predetermined time duration, wherein the internal compartment is in operative communication with the vacuum chamber via only the outgassing orifice, and adjusting the temperature of the internal compartment to a predefined testing temperature; and
(vii) monitoring a rate and/or amount of outgassing from the sample via a CQCM located outside of the outgassing orifice along a second imaginary line extending perpendicularly through the outgassing orifice when the LD is in the LD-closed state and the TD is in the TD-closed state.

19. The method of claim 18, wherein
the initiating the verification operation occurs after the rate of outgassing from the sample detected by the RGA reaches below the predetermined level for the predetermined time duration, and
the predetermined level comprises a maximum acceptable outgassing rate and the predetermined time duration comprises from about 6 hours to about 48 hours, such as at least about any of the following: 6, 12, 18, and 24 hours, and/or at most about any of the following: 48, 36, and 24 hours.

20. The method of claim 18, wherein the rate of outgassing below the predetermined level for the predetermined time duration has an average rate with deviations from the average rate over the predetermined time duration not exceeding greater than about 10% from the average rate, such as at most any of the following: 10, 8, 6, 4, 2, and 1% from the average rate.
